(19) United States
(12) Patent Application Publication
(10) Pub. No.: US 2017/0156235 A1
(43) Pub. Date: Jun. 1, 2017

(54) HEAT DISSIPATION APPARATUS

(71) Applicants: Inventec (Pudong) Technology Corporation, Shanghai (CN); INVENTEC CORPORATION, Taipei City (TW)

(72) Inventor: Wei-Yi LIN, TAIPEI CITY (TW)

(21) Appl. No.: 15/166,284

(22) Filed: May 27, 2016

(30) Foreign Application Priority Data
Nov. 27, 2015 (CN) 201510851569.3

(51) Int. Cl. H05K 7/20

(52) U.S. Cl. CPC H05K 7/2039

(57) ABSTRACT

Heat-dissipation apparatus includes an air-guiding plate, and a fan module, including a housing, a fan unit and a closure component. The housing has a tongue portion, an outlet, and an inlet, having a first portion and a second portion. The fan unit is pivotally-disposed inside the housing, and can unidirectionally rotate. Compression zone defined between the sidewall and the fan unit is originated from the tongue portion to the outlet. The closure component can selectively open or close the outlet. The air-guiding plate is pivotally-connected between the first portion and the second portion, and extended into the housing. When the heat-dissipation apparatus operates normally, the air-guiding plate is blocked between the compression zone and the second portion, and the outlet is opened. When the heat-dissipation apparatus operates deducting, the air-guiding plate is blocked between the compression zone and the first portion, and the outlet is closed.

### RELATED APPLICATIONS

This application claims priority to Chinese Application Serial Number 201510851569.3, filed Nov. 27, 2015, which is herein incorporated by reference.

### BACKGROUND

Field of Invention

The present disclosure relates to a heat dissipation apparatus. More particularly, the present disclosure relates to a self-dedusting fan heat dissipation apparatus.

Description of Related Art

Generally speaking, when a computing equipment, such as notebook, personal computer (PC) etc., is operating properly, the computing equipment usually needs heat-dissipated modules, such as heat dissipated fins, a fan module, a heat-guiding pipe, to release or diffuse heat generated from computing components or other components. Therefore, the heat-dissipated modules of a computing equipment are able to avoid or reduce heat accumulated in a housing of the computing equipment, in which the accumulated heat may arise temperature within the housing, and influence the computing equipment under operating statue. Moreover, components of the computing equipment may be ruined or malfunctioned under high temperature induced by the accumulated heat. Although, heat-dissipated modules can be operated to release or diffuse the heat, a dust or foreign matters fell from circumstance may be easily accumulated on the heat-dissipated module during daily use, such as a space between heat dissipated fins or an outlet of a fan module . . . etc, to reduce exposed areas of heat-dissipated modules, and an airflow between the heat-dissipated modules may be obstructed. Therefore, the heat-dissipated modules may hardly exchange cold air or heat energy with circumstance, such that the heat dissipated efficiency of the heat-dissipated modules would be degenerated under the dust or foreign matters accumulated onto the heat-dissipated'module.

In some cases, dust or foreign matters may be accumulated on a space between heat dissipated fins or an outlet, to block the heat-dissipated modules exchanging cold air frequently with circumstance. Accordingly, the heat dissipated efficiency of the heat-dissipated modules would be degenerated, and heat would be accumulated to arise temperature of a computing equipment, which may influence the computing equipment being wined or malfunctioned. Consequently, the available structure of heat-dissipated modules, as described above, apparently exist inconvenience and defect, which need further improvement. To deal with the aforesaid problem, practitioners of ordinary skill in the art have striven to attain a solution, and the problem still lacks a suitable solution to be developed. Therefore, to deal with the aforesaid problem effectively is an important subject of research and development, and also a desired improvement in the art.

### SUMMARY

The present disclosure provides a heat dissipation apparatus includes a fan module, heat-dissipated fins, and an air-guiding plate. The fan module includes a housing, a fan unit and a closure component. The housing has an inner-housing space, an outlet, and an inlet, in which the inlet has a first portion and a second portion. The housing includes a sidewall, having a tongue portion. The fan unit is pivotally disposed inside the housing, and configured to rotate relative to the housing along a rotational direction. A compression zone is defined between the sidewall and the fan unit, and originated from the tongue portion to the outlet along the rotational direction. The closure component is disposed between the outlet and the inner-housing space, and configured to selectively open or close the outlet. The heat-dissipated fins are disposed at the first portion of the inlet. The air-guiding plate is pivotally connected to the housing between the first portion and the second portion of the inlet, and extended into the inner-housing space. When the heat dissipation apparatus is working in a first mode, the air-guiding plate is blocked between the compression zone and the second portion of the inlet, and the closure component opens the outlet. When the heat dissipation apparatus is working in a second mode, the air-guiding plate is blocked between the compression zone and the first portion of the inlet, and the closure component closes the outlet.

It is to be understood that both the foregoing general description and the following detailed description are by examples, and are intended to provide further explanation of the invention as claimed.

### BRIEF DESCRIPTION OF THE DRAWINGS

The disclosure can be more fully understood by reading the following detailed description of the embodiment, with reference made to the accompanying drawings as follows:

FIG. 1 is a three dimensional view of a heat dissipation apparatus working in a first mode according to an embodiment of the present disclosure.

FIG. 2 is a top perspective view of a heat dissipation apparatus working in a first mode, as shown in FIG. 1, according to an embodiment of the present disclosure.

FIG. 3 is a three dimensional view of a heat dissipation apparatus working in a second mode according to an embodiment of the present disclosure.

FIG. 4 is a top perspective view of a heat dissipation apparatus working in the second mode, as shown in FIG. 3, according to an embodiment of the present disclosure.

FIG. 5 is a top perspective view of a heat dissipation apparatus working in a first mode according to another embodiment of the present disclosure.

FIG. 6 is a top perspective view of a heat dissipation apparatus working in a second mode according to another embodiment of the present disclosure.

Corresponding numerals and symbols in the different figures generally refer to corresponding parts unless otherwise indicated. The figures are drawn to clearly illustrate the relevant aspects of the embodiments and are not necessarily drawn to scale.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

It will be understood that when an element is referred to as being “on”, “over” another element, it can be directly on the other element or intervening elements may be present therebetween. In contrast, when an element is referred to as being “directly on” another element, there are no intervening elements present.

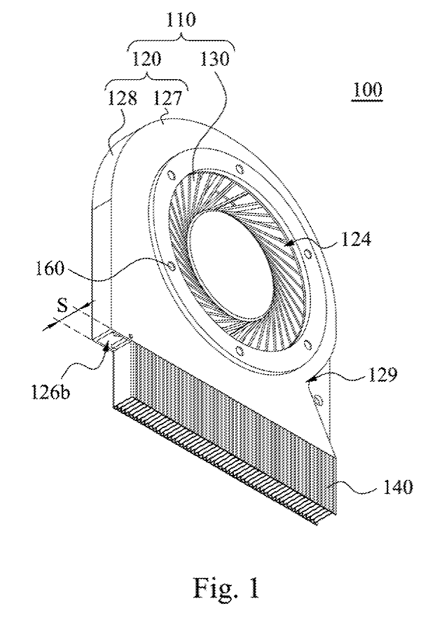

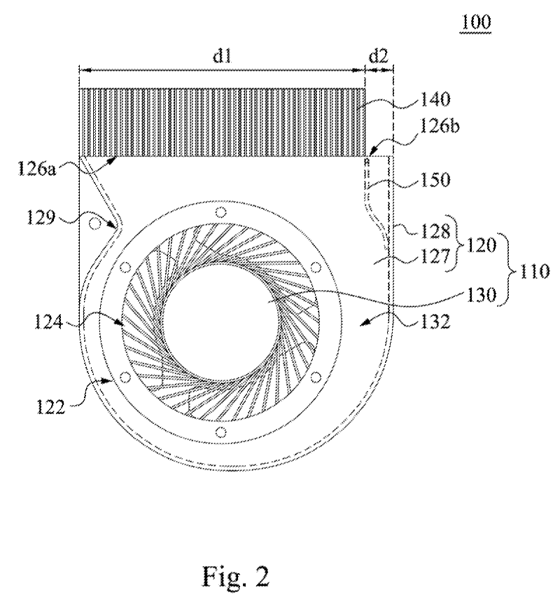

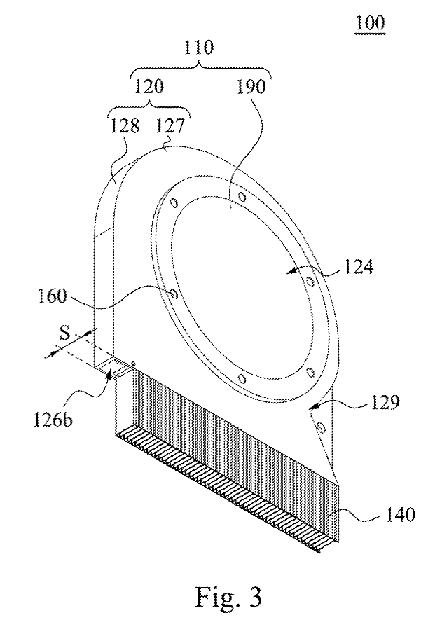

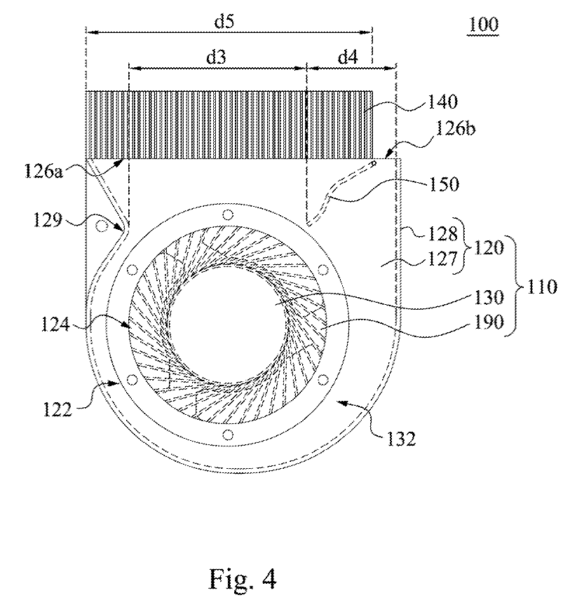

FIG. 1 illustrates a three dimensional view of a heat dissipation apparatus 100 working in a first mode, in which the first mode may be represented as a normal mode, according to an embodiment of the present disclosure. FIG. 2 illustrates a top perspective view of a heat dissipation apparatus 100 working in the first mode, as shown in FIG. 1, according to an embodiment of the present disclosure. As shown in FIG. 1 and FIG. 2, a heat dissipation apparatus 100 includes a fan module 110, heat-dissipated fins 140, and an air-guiding plate 150 (as shown in FIG. 2). The fan module 110 includes a housing 120, a fan unit 130 and a closure component 190 (as shown in FIG. 3 or FIG. 4). The housing 120 has an inner-housing space 122, an outlet 124, and an inlet. The housing 120 includes a sidewall 128. In some embodiments the housing 120 may further includes base plates 127, the inner-housing space 122 is defined by the sidewall 128 and the base plates 127 collectively. The outlet 124 is located on one of the base plates 127. When the heat dissipation apparatus 100 is working in the first mode or normal mode, the outlet 124 can be opened for interconnecting the inner-housing space 122 and circumstance, to exhale heated air out to circumstance. The inlet has a first portion 126a and a second portion 126b. The sidewall 128 has a tongue portion 129. The fan unit 130 is pivotally disposed inside the inner-housing space 122, and configured to rotate relative to the housing 120 along a rotational direction. A compression zone 132 is defined between the sidewall 128 and the fan unit 130, and originated from the tongue portion 129 to the outlet 124 along the rotational direction. The closure component 190 is disposed between the outlet 124 and the inner-housing space 122, and configured to selectively open or close the outlet 124. On the other hand, the closure component 190 can be selectively blocked between the outlet 124 and the inner-housing space 122, or removed from the outlet 124 for interconnecting the inner-housing space 122 and circumstance. in some embodiments, the heat-dissipated fins 140 are disposed at the first portion 126a of the inlet, outside the housing 120. The air-guiding, plate 150 is pivotally connected to the housing 120 between the first portion 126a and the second portion 126b of the inlet, and extended into the inner-housing space 122.

When the heat dissipation apparatus 100 is working in a first mode or a normal mode, the closure component 190 is removed from the outlet 124, to open the outlet 124, such that the inner-housing space 122 is interconnected to circumstance. In the meanwhile, the air-guiding plate 150 is rotated relative to the housing 120, and blocked between the compression zone 132 and the second portion 126b of the inlet. Owing to the compression zone 132 and the second portion 126b are disconnected inside the inner-housing space 122 under the first mode, an airflow entered the inner-housing space 122 through the first portion 126a of the inlet may be propelled and compressed by the fan unit 130 within the compression zone 132. Subsequently, the compressed airflow may be exhaled outside the fan module 110 through the outlet 124. When the heat dissipation apparatus 100 is working in the normal mode, the air-guiding plate 150 may isolate or separate the second portion 126b of the inlet from the inner-housing space 122, such that the airflow is restricted to leave the fan module 110 from the outlet 124.

FIG. 3 illustrates a three dimensional view of a heat dissipation apparatus 100 working in a second mode, in which the second mode may be represented as a dedusting mode according to an embodiment of the present disclosure. FIG. 4 illustrates a top perspective view of a heat dissipation apparatus 100 working in a second mode, as shown in FIG. 3, in which the fan unit 130 of the heat dissipation apparatus 100 covered by the closure component 190 is drawn by dotted lines, according to an embodiment of the present disclosure. As shown in FIG. 3 and FIG. 4, when the heat dissipation apparatus 100 is working in a second mode or a dedusting mode, the closure component 190 is blocked between the inner-housing space 122 and the outlet 124, to close the outlet 124. in the meanwhile, the air-guiding plate 150 is rotated relative to the housing 120, and blocked between the compression zone 132 and the first portion 126a of the inlet. Airflow may be propelled and compressed by fan unit 130 within the compression zone 132, and expelled from the second portion 126b of the inlet connected to the inner-housing space 122, to leave the fan module 110. As a consequence, a negative pressure zone may be generated between the compression zone 132 and the first portion 126a of the inlet, such that the negative pressure zone may attract an airflow inhaled from the first portion 126a of the inlet, and subsequently the airflow is flowed into the compression zone 132 to undergo repetitive processes, such as propelled and compressed by fan unit 130.

Due to the air-guiding plate 150 installed inside the housing 120 of the fan module 110 is switchable, which can be selectively switched between the normal mode where the air-guiding plate 150 is abutted against the sidewall 128, and blocked between the compression zone 132 and the second portion 126b of the inlet, and the dedusting mode where the air-guiding plate 150 is moved away from the sidewall 128, and blocked between the compression zone 132 and the first portion 126a of the inlet. Therefore, an airflow propelled and compressed by the fan unit 130 within the compression zone 132 can be guided through the air-guiding plate 150 and the closure component 190 collaboratively, and the airflow can be selectively exhaled outside the fan module 110 from the outlet 124 under the normal mode, or the second portion 126b of the inlet under the dedusting mode, without varying a rotation direction of the fan unit 130.

In addition, when the outlet 124 is closed by the closure component 190, and the air-guiding plate 150 is blocked between the compression zone 132 and the first portion 126a of the inlet, the fan unit 130 may propel the compressed airflow from the first portion 126a toward the second portion 126b, to generate a negative pressure for attracting airflow flowed through the first portion 126a and the heat-dissipated fins disposed outside the first portion 126a. Due to the cross-sectional area of the second portion 126b is lesser than the cross-sectional area of the outlet 124, consequently, the airflow flowed through the heat-dissipated fins 140 disposed outside the first portion 126a under the dedusting mode can be greater, comparing to the normal mode. Therefore, the airflow generated under the dedusting mode can remove residual dust on the heat dissipation apparatus 100 disposed outside the first portion 126a, for example, dust attached on the heat-dissipated fins 140. The dust can be carried by the airflow flowed from the first portion 126a to the compression zone 132, and left the heat dissipation apparatus 100 through the second portion 126b. As a consequence, dust accumulated on the heat-dissipated fins 140 and fan module 110 can be removed from the heat dissipation apparatus 100, without varying a rotation direction of the fan unit 130, to reduce or avoid the accumulated dust influenced airflow flowing into the fan module 110, and further improve the working efficiency and the heat-exchanging efficiency of the heat dissipation apparatus 100.

Referring to the FIG. 4, in some embodiments, the cross-sectional area of the first portion 126a of the inlet is greater than the cross-sectional area of the second portion 126b of the inlet. On the other hand, the first portion 126a of the inlet has a width dl, the second portion 126b of the inlet has a width d2, and the first portion 126a and the second portion 126b have a same height, such as a height S. Then, the width dl of the first portion 126a is greater than the width d2 of the second portion 126b. As a consequence, a speed of the airflow flowed through the first portion 126a is lesser than a speed of the airflow flowed through the second portion 126b, to generate a pressure difference between the first portion 126a and the second portion 126b for the airflow flowed more smoothly. Therefore, the first portion 126a and the second portion 126b, described herein, can reduce or avoid the dust carried by the airflow accumulated inside the inner-housing space 122, resulting from that the airflow generated by the pressure difference is too weak to carry the dust left from the second portion 126b, which may further influence an operation of the heat dissipation apparatus 100.

In some embodiments, when the heat dissipation apparatus 100 is working in the second mode or the dedusting mode, a shortest distance d3 between an end of the air-guiding plate 150 away from the inlet and a side of the sidewall 128 closed to the first portion 126a of the inlet, is greater than a shortest distance d4 between the end of the air-guiding plate 150 away from the inlet and a side of the sidewall 128 closed to the second portion 126b of the inlet. That is, when the heat dissipation apparatus 100 is operating on the dedusting mode, a side of the inner-housing space 122 closed to the inlet is blocked and partitioned into two parts by the air-guiding plate 150, in which a cross-sectional area of the part closed to the first portion 126a is greater than a cross-sectional area of the part closed to the second portion 126b. As a consequence, a speed of the airflow flowed through the first portion 126a is lesser than a speed of the airflow flowed through the second portion 126b, to generate a pressure difference between the first portion 126a and the second portion 126b for the airflow flowed more smoothly from the first portion 126a of the inlet to the second portion 126b, which is propelled by the fan unit 130.

In some embodiments, when the heat dissipation apparatus 100 is working in the second mode or the dedusting mode, the cross-sectional area of the first portion 126a of the inlet is greater than a cross-sectional area formed between the end of the air-guiding plate 150 away from the inlet and the tongue portion 129 within the housing 120. On the other hand, in some embodiments, when the heat dissipation apparatus 100 is operating on the dedusting mode, the first portion 126a of the inlet has a width d5, the shortest distance between the end of the air-guiding plate 150 away from the inlet and the tongue portion 129 has a width d3, and the first portion 126a and the inner-housing space have a same height, as a height S. The width d5 of the first portion 126a is greater than the width d3 between the end of the air-guiding plate 150 away from the inlet and the tongue portion 129. As a consequence, the airflow can be attracted by a negative pressure generated by the fan unit 130, a speed of the airflow flowed through the first portion 126a is lesser than a speed of the airflow flowed between the end of the air-guiding plate 150 away from the inlet and the tongue portion 129. The airflow can be compressed before entering the fan unit 130 for further compressed, such that the airflow may flow more smoothly, from the fan unit 130 to the second portion 126b.

It should be noted that, the cross-sectional area of the first portion 126a of the inlet, the cross-sectional area of the second portion 126b of the inlet, a cross-sectional area of the part closed to the first portion 126a, a cross-sectional area of the part closed to the second portion 126b, in which a side of the inner-housing space 122 closed to the inlet is blocked and partitioned into two parts by the air-guiding plate 150, and the cross-sectional area formed between the end of the air-guiding plate 150 away from the inlet and the tongue portion 129, described herein, are only exemplary, not intended to limit the present disclosure. It should be understood that, aspect of the cross-sectional area, described above, could be adjusted to actual demand by those skilled in the art, without departed from the scope or the spirits of the present disclosure. That is to say, prerequisite of the heat dissipation apparatus 100 is, when the heat dissipation apparatus 100 is working in the dedusting mode, the dust is removed from the heat-dissipated fins 140, and the removed dust can be carried by an airflow, and exhaled into circumstance from the second portion 126b of the inlet.

Referring to FIG. 3, in some embodiments, the closure component 190 may include a shutter aperture. The fan module 110 may further include a controller 160. The controller 160 can selectively close or open the shutter aperture. It should be understood that, the closure component 190, described herein, is only an exemplary, not intended to limit the present disclosure. The closure component 190 could be adjusted to actual demand by those skilled in the art, without departed from the scope or the spirits of the present disclosure. That is to say, prerequisite of the closure component 190 is that the closure component 190 can be controlled by the controller 160 to selectively close or open the shutter aperture, in order to disconnect or interconnect the inner-housing space 122 and circumstance through the outlet 124.

In some embodiments, an end of the air-guiding plate 150 away from the inlet is interlocked with or operative connected to the shutter aperture. When the shutter aperture is closed, the shutter aperture is interlocked or operative connected to the end of the air-guiding plate away from the inlet moving away from the sidewall. In some embodiments, the air-guiding plate 150 may be connected to the closure component 190 through a connecting rod for interlocking with the closure component 190. In some embodiments, the air-guiding plate 150 and the closure component 190 may move independently. In some embodiments, the heat dissipation apparatus 100 may include a valve and a connecting rod (not shown) connected to the air-guiding plate 150.

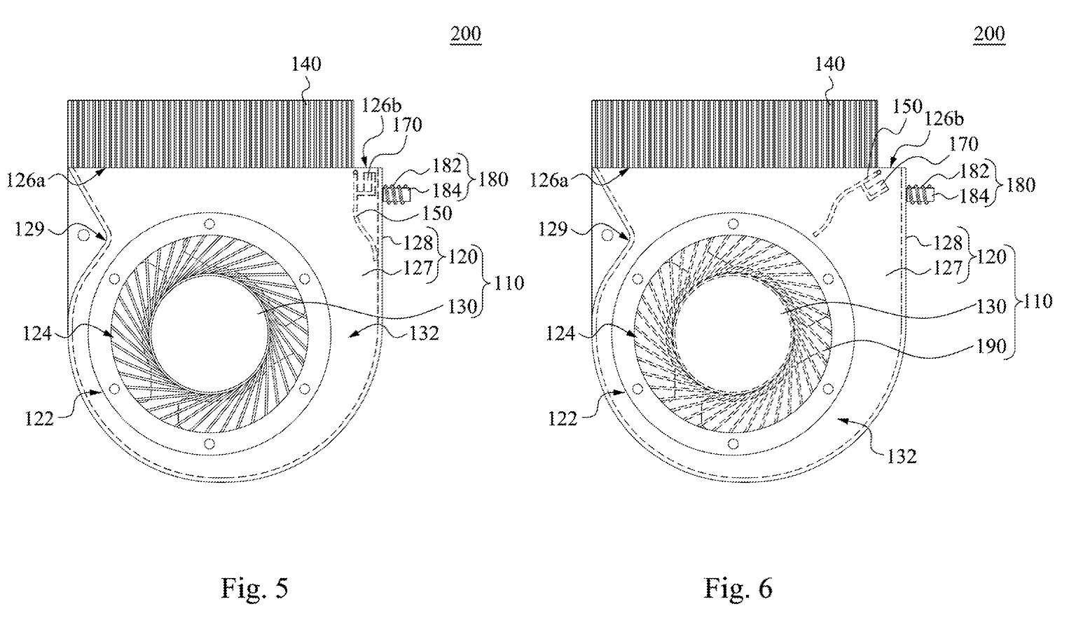

FIG. 5 is a top perspective view of a heat dissipation apparatus 200 working in a first mode, in which the first mode can be a normal mode according to another embodiment of the present disclosure. FIG. 6 is a top perspective view of a heat dissipation apparatus working in a second mode, in which the second mode can be a dedusting mode, according to another embodiment of the present disclosure. As shown in FIG. 5 and FIG. 6, in some embodiments, the air-guiding plate 150 may include a first magnetic component 170. In some embodiments, the first magnetic component 170 can be disposed at an end of the air-guiding plate 150 close to the second portion 126b of the inlet. The heat dissipation apparatus 200 may further include a second magnetic component 180. The second magnetic component 180 is configured to selectively magnetically attract or repel the first magnetic component 170.

In some embodiment, when the second magnetic component 180 magnetically attracts the first magnetic component, an end of the air-guiding plate 150 away from the inlet is rotated to be abutted against the sidewall 128, and the air-guiding plate 150 is blocked between the compression zone 132 and the second portion 126b of the inlet. In some embodiment, when the second magnetic component 180 magnetically repels the first magnetic component 170, the end of the air-guiding plate 150 away from the inlet is rotated away from the sidewall 128, and the air-guiding plate 150 is blocked between the compression zone 132 and the first portion 126a of the inlet.

In some embodiments, the second magnetic component 180 includes a coil 182 and a power supply (not shown). In some embodiments, the second magnetic component 180 may further include a magnetisable core 184, surrounded by the coil 182. in some embodiments, the magnetisable core 184 is insulated from the coil 182. The power supply is electrically connected to the coil 182. In some embodiment, the power supply can be an alternative current (AC) power supply or switchable direct current (DC) power supply. As shown in FIG. 6, when the power supply generates a first current, the second magnetic component 180 is induced to magnetically repel the first magnetic component 170. The first magnetic component 170 being repelled may actuate the end of the air-guiding plate 150 away from the inlet rotated away from the sidewall 128, and the air-guiding plate 150 is blocked between the compression zone 132 and the first portion 126a of the inlet. For example, a side of the first magnetic component 170 facing the sidewall 128 is north pole, and the power supply may generate the first current to induce a side of the magnetisable core 184 and the coil 182 facing toward the first magnetic component 170 into a north pore to repel the first magnetic component 170. Subsequently, the first magnetic component 170 being repelled rotates the end of the air-guiding plate 150 away from the inlet moving away from the sidewall 128. It should be understood that, the example, described herein, is not intended to limit the present disclosure, could be adjusted to actual demand by those skilled in the art. That is to say, prerequisite of the second magnetic component 180 is to repel the first magnetic component 170 rotated the end of the air-guiding plate 150 away from the inlet moving away from the sidewall 128, when the power supply generates a first current to induce the magnetisable core 184 and the coil 182 being magnetized.

A shown in FIG. 5, in some embodiments, when the power supply generates a second current, having an opposite direction of current comparing to the first current. The second magnetic component 180 is induced to magnetically attract the first magnetic component 170. The first magnetic component 170 being attracted may actuate the end of the air-guiding plate 150 away from the inlet abutted against the sidewall 128, and the air-guiding plate 150 is blocked between the compression zone 132 and the second portion 128b of the inlet. For example, a side of the first magnetic component 170 facing the sidewall 128 is north pole, and the power supply may generate the second current to induce the side of the magnetisable core 184 and the coil 182 facing toward the first magnetic component 170 into a south pore to attract the first magnetic component 170. Subsequently, the first magnetic component 170 being attracted rotates the end of the air-guiding plate 150 away from the inlet moving toward the sidewall 128, It should be understood that, the example, described herein, is not intended to limit the present disclosure, could be adjusted to actual demand by those skilled in the art. That is to say, prerequisite of the second magnetic component 180 is to attract the first magnetic component 170 rotated the end of the air-guiding plate 150 toward the inlet moving away from the sidewall 128, when the power supply generates a second current to induce the magnetisable core 184 and the coil 182 being magnetized.

In some embodiments, when the end of the air-guiding plate 150 away from the inlet is abutted against the sidewall 128, the power supply may cease to generate the second current, and the first magnetic component 170 is magnetically attracted with the magnetisable core 184. For example, the magnetisable core 184 may be a material having temporary ferromagnetic, which can be induced by the coil 182, and transformed into different magnetized arrangement. After the first magnetic component 170 approaches the magnetisable core 184, and the magnetisable core 184 is already temporarily magnetized. Even though, the current on the coil 182 being cut off, the first magnetic component 170 may keep magnetically attracted with the temporarily magnetized magnetisable core 184, till a first current generated by the power supply.

Summarized from the above, a heat dissipation apparatus includes a fan module, heat-dissipated fins, and an air-guiding plate. The fan module includes a housing, a fan unit and a closure component. The housing has an inner-housing space, an outlet, and an inlet, in which the inlet has a first portion and a second portion. The housing includes a sidewall, having a tongue portion. The fan unit is pivotally disposed inside the housing, and configured to rotate relative to the housing along a rotational direction. A compression zone is defined between the sidewall and the fan unit, and originated from the tongue portion to the outlet along the rotational direction. The closure component is disposed between the outlet and the inner-housing space, and configured to selectively open or close the outlet. The heat-dissipated fins are disposed at the first portion of the inlet. The air-guiding plate is pivotally connected to the housing between the first portion and the second portion of the inlet, and extended into the inner-housing space. When the heat dissipation apparatus is working in a first mode, the air-guiding plate is blocked between the compression zone and the second portion of the inlet, and the closure component opens the outlet. When the heat dissipation apparatus is working in a second mode, the air-guiding plate is blocked between the compression zone and the first portion of the inlet, and the closure component closes the outlet.

Although some embodiments of the present disclosure and their advantages have been described in detail, it should be understood that various changes, substitutions, and alterations can be made herein without departing from the spirit and scope of the disclosure as defined by the appended claims. For example, it will be readily understood by those skilled in the art that many of the features, functions, processes, and materials described herein may be varied when remaining within the scope of the present disclosure. Moreover, the scope of the present application is not intended to be limited to the particular embodiments of the process, machine, fabricate, composition of matter, means, methods, and steps described in the specification. As one of ordinary skill in the art will readily appreciate from the disclosure of the present disclosure, processes, machines, fabricate, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, fabricate, compositions of matter, means, methods, or steps.

What is claimed is:

1. A heat dissipation apparatus, comprising:
a fan module, comprising:
a housing having an inner-housing space, an outlet, and an inlet, the housing comprising a sidewall, wherein the inlet has a first portion and a second portion, and the sidewall has a tongue portion;
a fan unit pivotally disposed inside the housing and configured to rotate relative to the housing along a rotational direction, wherein a compression zone is defined between the sidewall and the fan unit, and originated from the tongue portion to the outlet along the rotational direction; and
a closure component disposed on the outlet, and configured to selectively open or close the outlet;
a plurality of heat-dissipated fins disposed at the first portion of the inlet; and
an air-guiding plate pivotally connected to the housing between the first portion and the second portion of the inlet, and extended into the inner-housing space,
wherein when the heat dissipation apparatus is working in a first mode, the air-guiding plate rotates to be blacked between the compression zone and the second portion of the inlet, and the closure component opens the outlet, and when the heat dissipation apparatus is working in a second mode, the air-guiding plate rotates to be blocked between the compression zone and the first portion of the inlet, and the closure component closes the outlet.

2. The heat dissipation apparatus of claim 1, wherein the closure component comprises a shutter aperture, wherein the fan module further comprises a controller configured to selectively close or open the shutter aperture.

3. The heat dissipation apparatus of claim 2, wherein an end of the air-guiding plate away from the inlet is operatively connected with the shutter aperture, wherein when the shutter aperture is closed, the shutter aperture actuates the end of the air-guiding plate away from the inlet to move away from the sidewall.

4. The heat dissipation apparatus of claim 1, wherein the air-guiding plate comprises a first magnetic component, the heat dissipation apparatus further comprises a second magnetic component configured to selectively magnetically attract or repel the first magnetic component.

5. The heat dissipation apparatus of claim 4, wherein when the second magnetic component magnetically attracts the first magnetic component, an end of the air-guiding plate away from the inlet is rotated to be abutted against the sidewall, and the air-guiding plate is blocked between the compression zone and the second portion of the inlet.

6. The heat dissipation apparatus of claim 4, wherein when the second magnetic component magnetically repels the first magnetic component, an end of the air-guiding plate away from the inlet is rotated away from the sidewall, and the air-guiding plate is blocked between the compression zone and the first portion of the inlet.

7. The heat dissipation apparatus of claim 4, wherein the second magnetic component comprises:
a coil; and
a power supply electrically connected to the coil,
wherein when the power supply generates a first current, the second magnetic component magnetically repels the first magnetic component, to actuate an end of the air-guiding plate away from the inlet rotated away from the sidewall, and the air-guiding plate is blocked between the compression zone and the first portion of the inlet.

8. The heat dissipation apparatus of claim 7, wherein when the power supply generates a second current having an opposite direction of current comparing to the first current, the second magnetic component magnetically attracts the first magnetic component, to actuate an end of the air-guiding plate away from the inlet abutted against the sidewall, and the air-guiding plate is blocked between the compression zone and the second portion of the inlet.

9. The heat dissipation apparatus of claim 7, wherein the second magnetic component further comprises a magnetisable core surrounded by the coil.

10. The heat dissipation apparatus of claim 9, wherein when the end of the air-guiding plate away from the inlet is abutted against the sidewall, the power supply ceases generating the second current, and the first magnetic component is magnetically attracted with the magnetisable coil.

11. The heat dissipation apparatus of claim 1, wherein a cross-sectional area of the first portion of the inlet is greater than a cross-sectional area of the second portion of the inlet.

12. The heat dissipation apparatus of claim 1, wherein when the heat dissipation apparatus is working in the second mode, a first shortest distance, between an end of the air-guiding plate away from the inlet and a side of the sidewall closed to the first portion of the inlet, is greater than a second shortest distance, between the end of the air-guiding plate away from the inlet and a side of the sidewall closed to the second portion of the inlet.

13. The heat dissipation apparatus of claim 1, wherein when the heat dissipation apparatus is working in the second mode, a cross-sectional area of the first portion of the inlet is greater than a cross-sectional area formed between an end of the air-guiding plate away from the inlet and the tongue portion within the housing.
